(19) United States
(12) Patent Application Publication
(10) Pub. No.: US 2017/0125976 A1
(43) Pub. Date: May 4, 2017

(54) LASER OSCILLATION DEVICE FOR MULTIPLEXING AND OUTPUTTING LASER LIGHT

(71) Applicant: FANUC CORPORATION, Yamanashi (JP)

(72) Inventor: Takanori Sato, Yamanashi (JP)

(73) Assignee: FANUC CORPORATION, Yamanashi (JP)

(21) Appl. No.: 15/333,702

(22) Filed: Oct. 25, 2016

(30) Foreign Application Priority Data
Oct. 28, 2015 (JP) 2015-211801

(51) Int. Cl. H01S 5/042; H01S 5/40; H01S 3/0941; H01S 5/06; H01S 3/067

(52) U.S. Cl. CPC H01S 5/042; H01S 5/0617; H01S 3/0675; H01S 3/09415; H01S 5/4025

(57) ABSTRACT

A laser oscillation device herein cumulates a value in which a weighting coefficient determined according to a value of a current that has driven light sources is multiplied by a drive time of the light sources every time each of the light source is driven, and stores a cumulative value obtained from thus cumulating while allowing the same to correspond to each of the light sources. Then, an instruction unit of the laser oscillation device determines the number of the light sources to radiate according to an output range of a laser output instruction, and by the number determined, the light sources are configured to be selected in an order from the smaller cumulative value by a selection unit, and only the selected light sources are allowed to radiate by a current control unit.

### BACKGROUND OF THE INVENTION

1. Field of the Invention

The present invention. relates to a laser oscillation device that multiplexes and outputs laser light radiated from a plurality of light sources.

2. Description of the Related Art

Conventionally, a laser oscillation device has been applied to a laser processing device that cuts, welds, modifies a surface, marks, trims, etc., of a component. Recently, in order to enhance an output of a laser oscillation device, a laser oscillation, device that multiplexes and outputs laser light from a plurality of light sources, such as a fiber laser and a direct diode laser (hereinafter referred to as DDL), has been developed.

The fiber laser includes a plurality of resonators having a plurality of semiconductor lasers for excitation that are the light sources as described above and an optical fiber for excitation, and multiplexes and outputs laser light from the plurality of resonators by a multiplexer. On the other hand, the CDL includes a plurality of semiconductor lasers that are the light sources as described above, and is configured to multiplex and output laser light of the plurality of semiconductor lasers by a multiplexer.

In the laser oscillation device, such as the fiber laser and the DDL as described above, an output control is performed at a predetermined rate relative to a rated output of the laser oscillation device. In this case, also at every light source provided to the laser oscillation device, an output control is performed at the same rate as the laser oscillation device. For example, it is assumed that a rated output of a single resonator is 500 W, while four resonators are provided, so that the rated output of the laser oscillation device is 2000 W. In such a configuration, when an output of the laser oscillation device is controlled to be 50% of the rated output of the laser oscillation device, i.e. 1000 W, an output of each of the four resonators is also controlled be 50% of the rated output of the resonators, i.e. 250 W. Then, an output of laser light oscillated from the resonators is measured and a feedback control of the output is performed, thereby accurately controlling the output of the laser oscillation device.

However, also in a case of the fiber laser and the DDL that can realize output enhancement, a stable output control is demanded not only during a high output instruction for cutting machining but also during a low output instruction for trimming, laser marking, and the like. For example, when the low output instruction of 100 W is given to the laser oscillation device having the rated output of 2000 W as described above, a value to be outputted by each of the four resonators is 25 W (=100 W/4). However, if a minimum output of the resonators is no more than a value in which the rated output of the resonators is multiplied by a predetermined rate, for example, 10% of the rated output, i.e. 50 W (=500 W×10%), a stable output control fails to be performed.

In this regard, Japanese Patent Application Laid-open No. 2012-227353 and Japanese Patent Application Laid-open No. 2006-12888 disclose a method of relatively lowering an output of a laser oscillation device during a low output instruction by reducing the number of resonators to oscillate, or allowing a current no more than a radiation threshold value of light sources to flow only through the light source selected.

Specifically, Japanese Patent Application Laid-open No. 2012-227353 discloses the laser oscillation device that collects and outputs laser light from the plurality of resonators. In the laser oscillation device, during the low output instruction, only one or two resonators from among the plurality of resonators are allowed to oscillate, thereby performing an output control in a range from a minimum output that can be controlled by each resonator to a rated output.

In addition, Japanese Patent Application Laid-open No. 2006-12888 discloses a laser light irradiation device that multiplexes laser light emitted from a plurality of laser light sources. In the laser light irradiation device, when a target value of a laser output is below a predetermined reference value, a part of a plurality of semiconductor lasers is selected and controlled by a current no less than a radiation threshold value. Accordingly, the rest of the semiconductor lasers is stopped or controlled by a current below the radiation threshold value.

However, in such a method as disclosed in Japanese Patent Application Laid-open No. 2012-227353 and Japanese Patent Application Laid-open No, 2006-12888, during the low output instruction, a specific light source is selected from among the plurality of light sources and allowed to radiate. Consequently, during the low output instruction, a load is concentrated on the specific light source, whereby the specific light source is apt to deteriorate and, as a result, a frequency of failures of the laser oscillation device also becomes high, which has been a problem.

### SUMMARY OF INVENTION

The present invention provides a laser oscillation device that can avoid concentration of a load on a specific light source during a low output instruction.

According to a first aspect of the present invention provided is a laser oscillation device including:
a resonator including at least two light sources; and
a multiplexer that multiplexes light radiated from the at least two light sources, in which the laser oscillation device includes:
a current control unit for variably controlling a current that drives each of the light sources;
a selection unit for selecting the light sources to radiate from among the at least two light sources; and
an instruction unit for giving instructions to the current control unit and the selection unit, respectively,
the instruction unit includes a storage unit for cumulating a value in which a weighting coefficient determined according to a value of a current that has driven the light sources is multiplied by a drive time of the light sources every time each of the light sources is driven, and storing a cumulative value obtained from thus cumulating while allowing the same to correspond to each of the light sources,
wherein the laser oscillation device is configured such that according to an output range of a laser output instruction to the laser oscillation device, a number of the light sources to radiate is determined, and by the number determined, the light sources are configured to be selected in an order from the smaller cumulative value by the selection unit, and only the selected light sources are allowed to radiate by the current control unit.

According to a second aspect of the present invention provided is the laser oscillation device according to the first aspect, in which the light sources are semiconductor lasers.

According to a third aspect of the present invention provided is the laser oscillation device according the first aspect, in which the light sources are semiconductor lasers for excitation, and the resonator includes an excitation medium that is excited by light of the semiconductor laser for excitation.

According to a fourth aspect of the present invention provided is the laser oscillation device according to any one of the first to third aspects, in which the instruction unit is configured to control a rest of the light sources except the selected light sources by a current more than zero and less than a radiation threshold value by the current control unit and the selection unit.

According to a fifth aspect of the present invention provided is the laser oscillation device according to any one of the first to forth aspects, in which the instruction unit is configured to uniformly subtract a numerical, value corresponding to the minimum cumulative value from among the cumulative value of each of the light sources that is stored in a storage unit of the instruction unit from the cumulative value of each of the light sources at a predetermined timing.

According to a sixth aspect of the present invention provided is the laser oscillation device according to any one of the first to fifth aspects, in which the resonator includes an additional storage unit, and the additional storage unit stores a table in which and from which and the cumulative value of each of the light sources can be written and read out.

According to a seventh aspect of the present invention provided is the laser oscillation device according to any one of the first to sixth aspects, in which the resonator includes a plurality of groups composed of the plurality of light sources, and wherein the laser oscillation device is configured such that the plurality of light sources are allowed to radiate per each of the groups.

### BRIEF DESCRIPTION OF THE DRAWINGS

These objects, features, and advantages of the present invention and other objects, features, and advantages will become further apparent from the detailed description of typical embodiments of the present invention that are illustrated in the accompanying drawings.

FIG. 1 is a block diagram illustrating a configuration of a laser oscillation device according to an embodiment of the present invention.

FIG. 2 is a block diagram illustrating a modification of the laser oscillation device as illustrated in FIG. 1.

FIG. 3 is a diagram illustrating a relationship between a current to each of light sources (laser radiation units) of a single resonator (oscillation module) and a value of a laser output instruction.

FIG. 4A is a diagram illustrating I-L characteristics (current-light output characteristics) of a single semiconductor laser.

FIG. 4B is a diagram illustrating a weighting coefficient in each of ranges of a drive current as illustrated in FIG. 4A.

FIG. 5 is a diagram illustrating a cumulative value obtained with respect to each of the four light sources (No. 1 to No. 4).

FIG. 6 is a diagram conceptually illustrating an overflow countermeasure of the cumulative value to be stored.

FIG. 7 is a diagram illustrating a table in which the number of the light sources (laser radiation units) and the cumulative value obtained with respect to each of the light sources (laser radiation units) are configured to correspond to each other.

FIG. 8 is a flowchart illustrating an example of processing for allowing the table in a numerical value storage unit of the resonator (oscillation module) to store the cumulative value.

FIG. 9 is a diagram illustrating a modification of the resonator (oscillation module) as illustrated in FIG. 1.

### DETAILED DESCRIPTION

Next, embodiments of the present invention will be described with reference to the drawings. In the following figures, the same components and functions will be assigned the same reference signs. In addition, it is assumed that the elements denoted by the same reference signs in different drawings denote elements having the same functions. Moreover, in order to facilitate understanding, these figures are suitably changed in scale. Further, in the following, as a laser oscillation device, a fiber laser and a DDL will be described as an example, to which, however, the present invention is not limited.

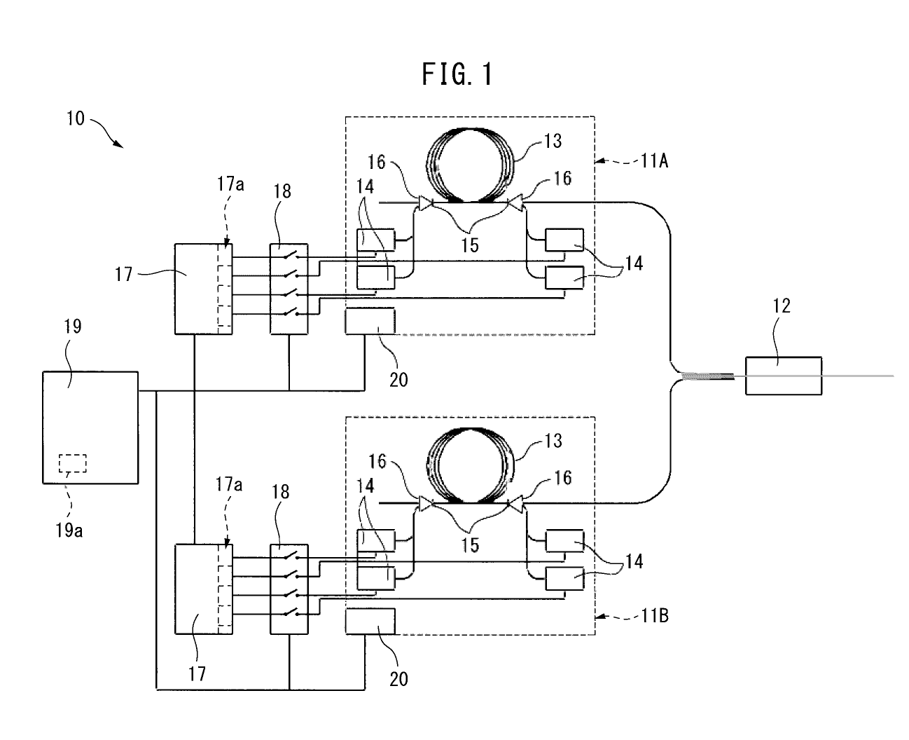

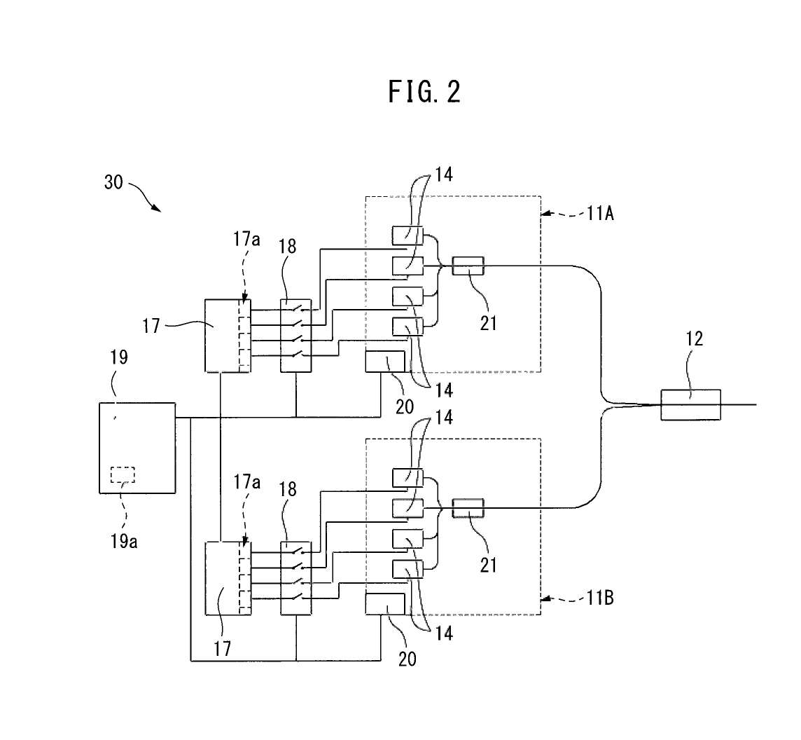

FIG. 1 is a block diagram illustrating a configuration of a laser oscillation device according to an embodiment of the present invention. FIG. 2 is a block diagram illustrating a modification of the laser oscillation device as illustrated in FIG. 1.

The laser oscillation device as illustrated in FIG. 1 is a fiber laser 10, and the laser oscillation device as illustrated in FIG. 2 is a direct diode laser (DDL) 30.

As illustrated in FIGS. 1 and 2, the fiber laser 10 or the DDL 30 includes a plurality of resonators (oscillation modules) 11A, 11B that oscillate laser light and a multiplexer (combiner) 12 that multiplexes laser light oscillated from each of the resonators 11A, 11B.

Such fiber laser 10 and DDL 30 are applied to a laser processing device that performs cutting, welding, surface modification, marking, trimming, and the like of a component. In this case, the laser light multiplexed by the multiplexer 12 as described above is guided through an optical fiber for processing (unillustrated) to a processing head of the laser processing device (unillustrated).

Note that, as apparent from FIGS. 1 and 2, the fiber laser 10 and the DDL 30 differ from each other in a configuration of each of the resonators (oscillation modules) 11A, 11B.

In a case of the fiber laser 10, as illustrated in FIG. 1, each of the resonators (oscillation modules) 11A, 11B includes one optical fiber for excitation 13 and four light sources (laser radiation units) 14 that are semiconductor lasers for excitation.

Specifically, the resonators 11A, 11B of the fiber laser 10 include the optical fiber for excitation 13 having a core doped by ytterbium (Yb) or erbium (Er) as an excitation medium, and, to each of two parts of the optical fiber for excitation 13 in a core length direction, a fiber bragg grating (FBG) 15 corresponding to a mirror of the resonators is provided. Further, light outputted from each of the light sources 14 that are semiconductor lasers for excitation is coupled to a clad part on a core outer side of the optical fiber 13 through a tapered fiber bundle (TFB) 16. Then, light of the semiconductor lasers for excitation is excited by the core of the optical fiber 13, and emitted from the FBG 15 on one side corresponding to an output mirror.

On the other hand, in a case of the DDL 30, as illustrated in FIG. 2, each of the resonators (oscillation modules) 11A, 11B includes the four light sources (laser radiation units) 14 that are semiconductor lasers and a multiplexer (combiner) 21 that multiplexes light radiated form each light source 14.

For example, when a rated output of the fiber laser 10 or the DDL 30 according to the present embodiment is 2000 W, each of the resonators 11A, 11B requires an output of 1000 W. Accordingly, at each light source 14, the semiconductor laser for excitation having a rated output of 250 W (1000 W/4) is used.

As a matter of course, in the present invention, the number of resonators constituting the fiber laser 10 or the DDL 30 (hereinafter also occasionally generally referred to as laser oscillation device) and the number of light, sources in each resonator are matters optionally determined according to a product specification.

In other words, in each of FIGS. 1 and 2, the two resonators 11A, 11B are illustrated, but the laser oscillation device of the present invention may include at least one resonator. In addition, with respect to each of the resonators 11A, 11B, the four light sources 14 are illustrated, but resonators applied to the present invention may include at least two light sources.

Further, as illustrated in FIGS. 1 and 2, the laser oscillation device according to the present embodiment includes two power source units 17 having a current control unit 17a that variably controls a current to be supplied to each of the four light sources 14 in each of the resonators 11A, 111. The power source units 17 are each connected through a selection unit 18 to the resonators 11A, 11B, respectively.

Further, the fiber laser 10 or the DDL 30 includes an instruction unit 19 that sends in accordance with a laser output instruction, a selection instruction and a current instruction that correspond to the laser output instruction to the selection units 18 and the current units 17, respectively. The instruction unit 19 is, for example, a numerical control device (NC device), and the laser output instruction as described above is read out when a processing program stored in advance in a numerical value storage unit 19a of the instruction unit 19 is performed.

Each selection unit 18 selects, in accordance with the selection instruction given from the instruction unit 19, the light sources to radiate from among the four light sources 14. Further, the current control units 17a of the respective power source units 17 each supply, in accordance with the current instruction given from the instruction unit 19, a current to the selected light sources.

On this occasion, the instruction unit 19 sends the selection instruction to the selection units 18 based on a selection number table in which an output range of the laser output instruction and the number of the light sources 14 to radiate are configured to correspond to each other. Further, the instruction unit 19 sends the current instruction to the current control units 17a based on a current value table in which the number of the light sources 14 for oscillating a laser output instructed and an instruction current value are configured to correspond to each other. The selection number table and the current value table are each stored in advance in the numerical value storage unit 19a of the instruction unit 19.

Then, the instruction unit 19 obtains an output of laser light oscillated from each of the resonators 11A, 11B and performs a control of feeding back the output to the current control units 17a of the respective power source units 17. In other words, in order that a total of the output of the light sources selected as described above amounts to a value of the laser output instruction, a current to be supplied to each selected light source is controlled.

Note that in order not to select the light sources 14 that cannot be used due to failures from among the plurality of (eight in the present example) light sources 14 provided to the laser oscillation device, it is preferable to further comprise an input unit (unillustrated) that inputs into the numerical value storage unit 19a of the instruction unit 19 whether or not each light source 14 can be used. Then, the instruction unit 19 preferably reflects information on whether or not each light source 14 can be used in the selection instruction and the current instruction as described above. In other words, preferably, the light sources 14 that cannot be used due to failures are removed from among the plurality of light sources 14 as described above, and then selection of the light sources 14 to radiate and current control are performed. In addition, the input unit as described above is provided so that even if there are the light sources 14 that cannot be used due to failures in each of the resonators 11A, 11B, the laser oscillation device can be temporarily used.

In the present embodiment, according to the output range of the laser output instruction, the number of the light sources 14 to radiate is determined in accordance with the selection number table as described above. Further, in the present embodiment, in consideration of a use frequency of and a load on each light source so far, which light sources are allowed to radiate is determined in accordance with the number of the light sources that is determined as described above.

First, determining the number of the light sources to rate according to the output range of the laser output instruction will be described.

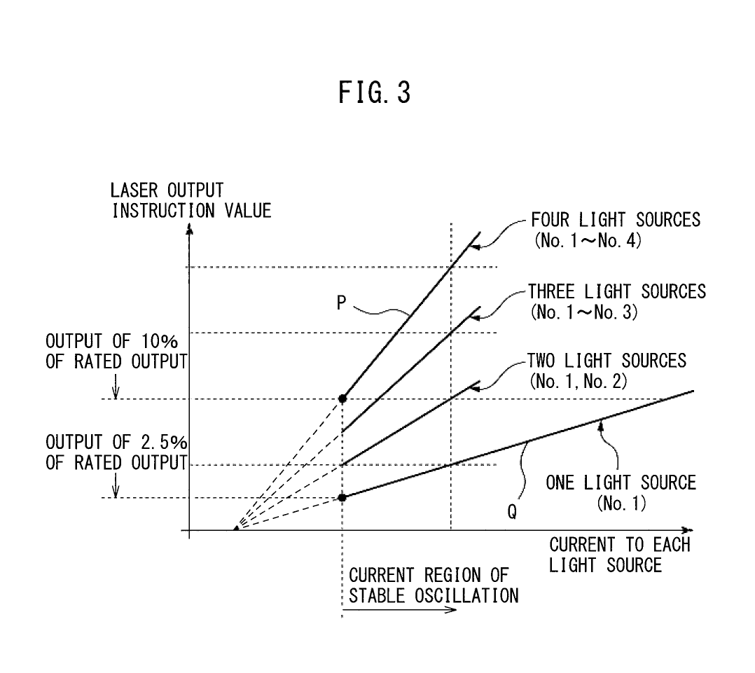

FIG. 3 is a diagram illustrating a relationship between a current to each of the light sources 14 (laser radiation units) of the single resonator (oscillation module) 11A and the value of the laser output instruction.

As apparent from FIG. 3, when the value of the laser output instruction to the laser oscillation device falls below 10% of the rated output of the laser oscillation device, the number of the light sources to radiate is reduced, whereby a stable output control can be performed. In other words, when all the four light sources 14 (No. 1 to No. 4) are allowed to radiate in the single resonator 11A, as indicated a line P in FIG. 3, a lower limit of the laser output instruction that allows stable oscillation to be performed is 10% of the rated output of the laser oscillation device. However, when the single light source 14, for example only the light source of No. 1 is selected to radiate, as indicated by line Q in FIG. 3, the lower limit of the laser output instruction that allows stable oscillation to be performed is lowered to 2.5% (=10%/4) of the rated output of the laser oscillation device.

Further, in a case of the present embodiment, since, as illustrated in FIGS. 1 and 2, the two resonators 11A, 11B including the four light sources 14 are provided each, the lower limit of the laser output instruction that allows stable oscillation to be performed can be lowered to 1.25% (=10%/8) of the rated output of the laser oscillation device. Note that in the present invention, since the number of resonators and the number of light sources in each resonator are not limited, the lower limit of the laser output instruction that allows stable oscillation to be performed can be lowered from 10% of the rated output of the laser oscillation device to (10%/(the number of resonators x the number of light sources in each resonator)).

Based on the above, the selection number table in which the output range of the laser output instruction and the number of the light sources 14 to radiate are configured to correspond to each other and the current value table in which the number of the light sources 14 for oscillating the laser output instructed and the instruction current value are configured to correspond to each other are created in advance. Then, such selection number table and current value table are stored in advance in the numerical value storage unit 19a of the instruction unit 19.

For example, when the output range of the laser output instruction is no less than 10% of the rated output of the laser oscillation device, the instruction unit 19 is configured to give, based on the selection number table as described above, the selection instruction for selecting all the light sources 14 to each selection unit 18. Further, the instruction unit 19 is configured to give, based on the current value table as described above, the current instruction for uniformly distributing a current no less than a radiation threshold value to all the light sources 14 to each power source unit 17. For example, when the rated output of the fiber laser 10 or the DDL 30 is 2000 W, if the laser output instruction of 1000 N (=2000 N×50%) is given, all the light sources 14 in the two resonators 11A, 11B are each controlled to have an output of 125 W (=1000 W/8). Note that it is assumed that the input, unit as described above has inputted into the numerical value storage unit 19a of the instruction unit 19 that the eight light sources 14 in the two resonators 11A, 11B can be used.

On the other hand, when the output range of the laser output instruction is less than 10% of the rated output of the laser oscillation device, only a part of the eight light sources 14 in the two resonators 11A, 11B is allowed to radiate, while the rest of the light sources is stopped or yet to radiate. Specifically, the instruction unit 19 is configured to give, based on the selection number table as described above, the selection instruction for selecting a part from among the eight light sources 14 to each selection unit 18. Further, the instruction unit 19 is configured to give, based on the current value table as described above, the current instruction for supplying a current no less than the radiation threshold value to the selected light sources 14 to each power source unit 17.

For example, when the rated output of the fiber laser 10 or the DDL 30 is 2000 N and each light source 14 has the rated output of 250 N, it is assumed that the laser output instruction of 50 N (=2000 W×2.5%) is given. In this case, only the single light source 14 is controlled to have an output of 50 W. Thereby, during the low output instruction of less than 10% of the rated output of the fiber laser 10 or the DDL 30, an output of the light sources 14 is not controlled to be less than 10% of the rated output of the light, sources 14, which allows an output control of the light sources 14 during the low output instruction to be stably performed.

Further, preferably, when a part of the plurality of light sources 14 provided to the laser oscillation device is selected and controlled by a current no less than the radiation threshold value as described above, the rest of the light sources 14 except the selected light sources 14 is also selected by the selection units 18 and controlled by a current more than zero and less than the radiation threshold value. Thereby, an output response property when the value of the laser output instruction is switched from a value less than 10% of the rated output of the laser oscillation device to a value that is substantially the rated output of the laser oscillation device is improved.

As thus described, when a part of the plurality of light sources 14 provided to the laser oscillation device is selected, the number of the light sources 14 to radiate is determined according to the output range of the laser output instruction in accordance with the selection number table as described above.

Further, in the present embodiment, in consideration of a use frequency of and a load on each light source 14 so far, which light sources 14 are allowed to radiate is determined in accordance with the number of the light sources 14 that is determined according to the output range of the laser output instruction. Hereinafter, this matter will be described in detail.

As a temperature of the semiconductor lasers increases when a relatively high drive current is applied to the semiconductor lasers, a lifetime of the semiconductor lasers used at the light sources 14 becomes shorter. In contrast, if the temperature of the semiconductor lasers does not substantially increase when a relatively low drive current is applied to the semiconductor lasers, the lifetime of the semiconductor lasers used at the light sources 14 becomes long. Accordingly, every time each of the light sources 14 is driven, a value in which a weighting coefficient determined according to a value of a drive current of the light sources 14 is multiplied by a drive time of the light sources 14 is cumulated, whereby a use frequency of and a load on each light source 14 so far can be numericalized.

Accordingly, in the present embodiment, a cumulative value obtained from the cumulation as described above is obtained with respect to all the light sources 14 provided to the laser oscillation device. Then, the cumulative value is used as a determination basis for which light sources 14 are selected when a switch to the low output instruction of less than 10% of the rated output of the laser oscillation device is made. Specifically, by the number of the light sources 14 that is determined according to the output range of the laser output instruction, the light sources 14 are selected in an order from the smaller cumulative value as described above, and the selected light sources 14 are allowed to radiate. Accordingly, concentration of a load on a specific light source can be prevented.

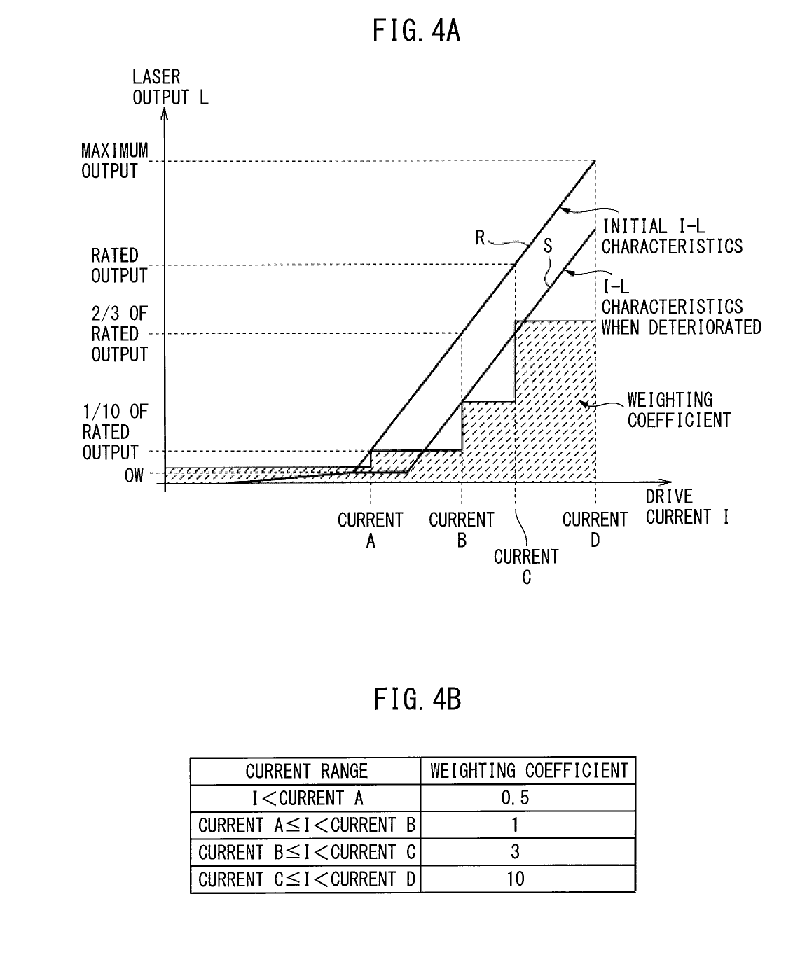

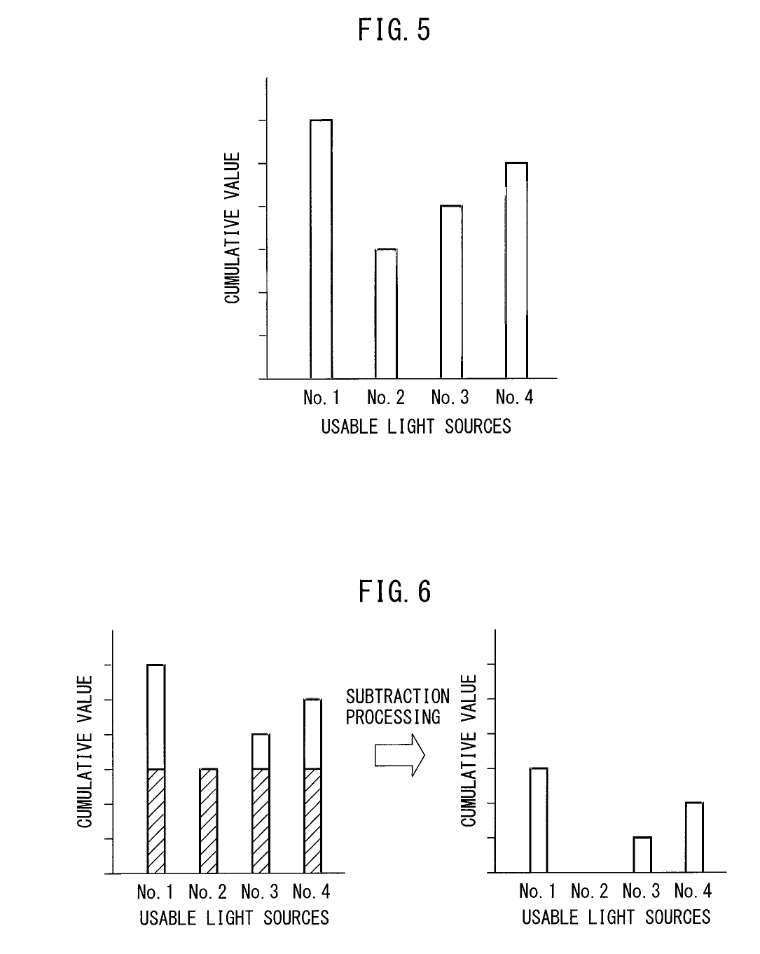

FIG. 4A is a diagram illustrating I-L characteristics (current-light output characteristics) of the single semiconductor laser, and FIG. 4B is a diagram illustrating the weighting coefficient in each of ranges of a drive current as illustrated in FIG. 4A, FIG. 5 is a diagram illustrating a cumulative value obtained with respect to each of the four light sources 14 (No. 1 to No. 4).

A line R in FIG. 4A indicates I-L characteristics of the initial semiconductor laser and line S in FIG. 4A indicates I-L characteristics of the semiconductor laser deteriorated due to a long-time use. As apparent from comparison of the line R with the line S, even in the same semiconductor laser, if the semiconductor laser deteriorates, a laser output relative to the same current lowers.

As described above, since there is a tendency in which the higher a drive current is, the shorter a lifetime of the semiconductor laser becomes, the weighting coefficient required to calculate cumulative value as described above is determined with respect to each current range of a drive current I when the semiconductor laser is allowed to radiate as illustrated in FIGS. 4A and 4B. In addition, the greater the current range is, the greater the weighting coefficient is configured to become.

Note that, in the present embodiment, as illustrated in FIG. 4A, the current range of the drive current I that determines the weighting coefficient as described above is partitioned, for example, by a current A, a current B, a current C, and a current D as described below. In other words, the current A is a drive current by which an output of 1/10 of a rated output of the semiconductor laser is obtained, the current B is a drive current by which an output of ⅔ of the rated output of the semiconductor laser is obtained, the current C is a drive current by which the rated output of the semiconductor laser is obtained, and the current D is a drive current by which a maximum output of the semiconductor laser that can be controlled is obtained. As a matter of course, the current range as illustrated in FIGS. 4A and 4B is an example, to which the present invention is not limited.

In addition, in the present embodiment, as illustrated in FIG. 5, for example, a value in which the weighting coefficient determined according to the drive current at each of the four light sources 14 (No. 1 to No. 4) is multiplied by the drive time of each light source 14 is cumulated with the passage of a laser processing time.

Specifically, a timer is activated at the same time when laser light is outputted by the laser output instruction, and the timer is stopped at a timing when a value of the laser output instruction is switched, thereby measuring the drive time of each light source 14 as described above. On this occasion, when the measured drive time includes a fraction after the decimal point, the fraction is rounded up to be one second. Then, with respect to each of the light sources 14, the value in which the weighting coefficient (see FIG. 4B) corresponding to a maximum value of an instruction current at the light sources 14 is multiplied by the drive time as described above is cumulated at each time when the laser output instruction is switched. Note that at each time when the value of the laser output instruction is switched, a time measured by the timer is reset. Thus, the cumulative value as described above can be obtained.

In the present embodiment, when the laser output instruction of no less than 10% of the rated output of the laser oscillation device is given, from the plurality of light sources 14 provided to the laser oscillation device, the light sources determined not to be used due to failures are removed, and the rest of the light sources is all allowed to radiate by the same current. In this case, the cumulative value uniformly increases relative to all the light sources allowed to radiate.

On the other hand, in a case of the low output instruction of less than 10% of the rated output of the laser oscillation device, from the plurality of light sources 14 provided to the laser oscillation device, the light sources determined not to be used due to failures are removed, and a part of the rest of the light sources is selected and allowed to radiate. Note that when the laser oscillation device is activated at less than 10% of the rated output for the first time, the determined number of the light sources 14 are selected in accordance with the number of the light sources 14 (No. 1 to No. 4). In a case of the low output instruction as described above, only the cumulative value corresponding to the selected light sources increases. Consequently, if the varied low output instruction of less than 10% of the rated output of the laser oscillation device is repeated, for example, as illustrated in FIG. 5, a difference between each cumulative value at the four light sources 14 (No. 1 to No. 4) occurs. In FIG. 5, the light sources 14 in descending order of the cumulative value are the light source 14 of No. 1, the light source 14 of No. 4, the light source 14 of No. 3, and the light source 14 of No. 2.

The cumulative value obtained with respect to each light source 14 as described above is stored in the numerical value, storage unit 19a of the instruction unit 19. Thereby, the instruction unit 19 can grasp a use frequency of and a load on each light source 14 so far using the cumulative value as described above.

Then, during the low output instruction, a part of the plurality of light sources 14 provided to the laser oscillation device, for example, the two light sources are selected, the instruction unit 19 refers to the cumulative value corresponding to each light, source 14 that is stored in the numerical value storage unit 19a of the instruction unit 19. Then, the instruction unit 19 is configured to select the two light sources in an order from the smaller cumulative value as described above, and allow the selected two light sources to radiate. For example, in FIG. 5, the light source 14 of No. 2 and the light source 14 of No. 3 are selected and allowed to radiate.

In other words, during the low output instruction, a part of the plurality of light sources 14 provided to the laser oscillation, device is selected and allowed to radiate, the light sources with a less use frequency and a less load so far are preferentially used. As a result, concentration of a load on a specific light source in an output control during a low output instruction can be prevented.

The cumulative value as described above is stored in the numerical value storage unit 19a of the instruction unit 19 as a variable for generating the selection instruction and the current instruction as described above. Accordingly, if the cumulative value continues to increase, the cumulative value may over beyond a storage capacity of the numerical value storage unit 19a of the instruction unit 19. FIG. 6 is a diagram conceptually illustrating a countermeasure against such an overflow of the cumulative value. In the overflow countermeasure as described above, as illustrated in FIG. 6, preferably, a numerical value corresponding to the minimum cumulative value from among the cumulative values of the four light sources (No. 1 to no. 4) is uniformly subtracted from the cumulative value of each of the four light sources (No. 1 to no. 4). Further, such subtraction processing is preferably performed at each certain time, or at each end of selecting the light sources as described above. Thus, the cumulative value as described above can be stored in the numerical value storage unit 19a without overflow of the cumulative value beyond a storage capacity of the numerical value storage unit 19a of the instruction unit 19.

In addition, in the present embodiment, from reasons as described below, as illustrated in FIGS. 1 and 2, each of the resonators 11A, 11B preferably includes an additional numerical value storage unit 20 and an input-output interface (unillustrated).

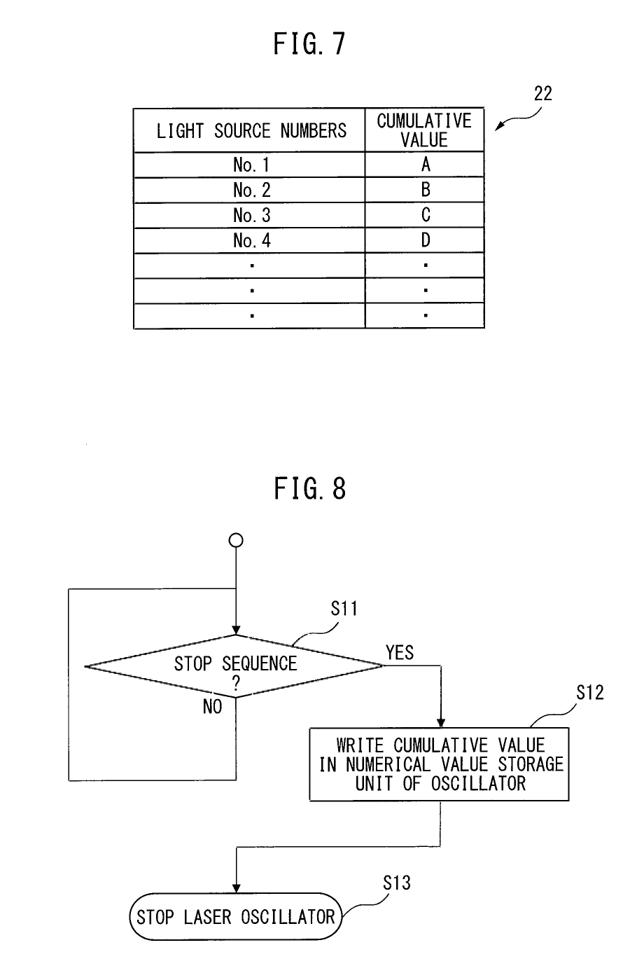

FIG. 7 is a diagram illustrating a table 22 in which the number of the light sources 14 (No. 1 to No. 4, etc.) and the cumulative value obtained with respect to each light source 14 (A to D, etc.) are configured to correspond to each other.

In the present embodiment, each of the resonators 11A, 11B is provided with the additional numerical value storage unit 20, whereby the table 22 as illustrated in FIG. 7 can be stored in the numerical value storage unit 20 in each of the resonators 11A, 11B. In other words, the cumulative value with respect to each light source 14 that is stored in the numerical value storage unit 19a of the instruction unit 19 as described above can be stored in the table 22 in the numerical value storage unit 20 of each of the resonators 11A, 11B. Although not illustrated in FIG. 7, the table 22 preferably also stores the drive time so far with respect to each light source 14 together with the cumulative value with respect to each light source 14.

Then, preferably, processing for storing the cumulative value with respect to each light source 14 in the table 22 in the numerical value storage unit 20 of each of the resonators 11A, 11B as described above is performed from the numerical value storage unit 19a of the instruction unit 19 via the input interface as described above to the numerical storage unit 20 at a predetermined timing.

FIG. 8 is a flowchart illustrating an example of processing for allowing the table 22 in the numerical value storage unit 20 of each of the resonators 11A, 11B (oscillation modules) to store the cumulative value. As illustrated in FIG. 8, in step S11, whether or not a stop sequence for stopping the laser oscillation device is performed is determined. When the stop sequence is performed, in step S12, the cumulative value with respect to each light source 14 as described above is written in the table 22 in the numerical value storage unit 20 of each of the resonators 11A, 11B. Subsequently, in step S13, the laser oscillation device is stopped.

In addition, the numerical value storage unit 20 and the input interface as described above are provided to each of the resonators 11A, 11B so that cumulative value data in the table 22 in the numerical value storage unit 20 of each of the resonators 11A, 11B can be read out to the exterior of the laser oscillation device. Thereby, confirmation of a use frequency and estimation of a lifetime, and the like, of each light source 14 in the resonators with respect to each of the resonators 11A, 11B can be performed. Further, when each of the resonators 11A, 11B is separately changed, numerical values in the table 22 in the numerical value storage unit 20 can be written over and reset.

Further, the resonator 11A or the resonator 11B in the laser oscillation device as described above is not limited to configurations as described in FIGS. 1 and 2.

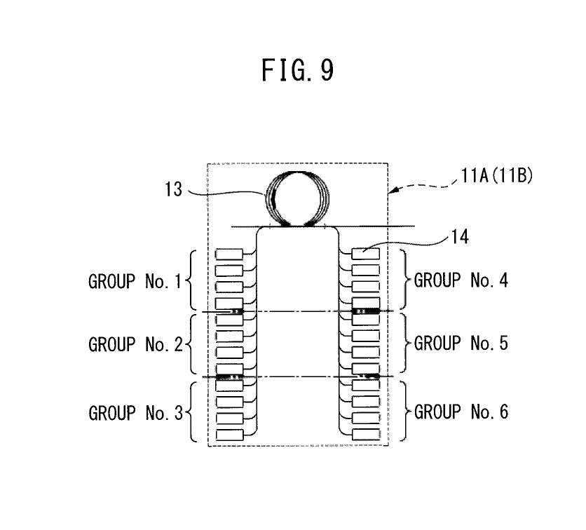

FIG. 9 is a diagram illustrating a modification of the resonator 11A or the resonator 11B as illustrated in FIG. 1.

As illustrated in FIG. 9, when the number of the light sources 14 provided to the resonator 11A (11B) is large, preferably, the large number of the light sources 14 are divided into a plurality of groups composed of the certain light sources, and per each group, all the light sources in the group are allowed to radiate. For example, in FIG. 9, six groups No. 1 to No. 6 are provided in the single resonator 11A (11B). Then, each of the groups No. 1 to No. 6 includes the four light sources 14. Such a configuration allows calculation of the cumulative value as described above and storage volume to be reduced compared to a case in which the light sources 14 are separately controlled, which accordingly simplifies the control.

Note that, in FIG. 9, a modification of the resonator 11A or the resonator 11B of the fiber laser 10 as illustrated in FIG. 1 is illustrated, but such a modification can be applied to the resonator 11A or the resonator 11B of the DDL 30 as illustrated in FIG. 2,

Thus, the laser oscillation device according to the embodiment as described above produces the following effects.

Every time each of the light sources 14 is driven, a value in which a weighting coefficient determined according to a value of a current that has driven the light sources 14 is multiplied by a drive time of the light sources 14 is cumulated, whereby a use frequency of and a load on each light source 14 so far can be numericalized. Further, the storage unit of the instruction 19 stores the cumulative value obtained from the cumulation as described above while allowing the same to correspond to each of the light sources 14. Consequently, during the low output instruction, a part of the light sources 14 is selected and allowed to radiate, the light sources 14 with a less use frequency and a less load so far can be grasped from the cumulative value stored in the storage unit of the instruction unit 19 and preferentially used. As a result, concentration of a load on a specific light source in an output control during a low output instruction can be prevented. In addition, since a specific light source is not repeatedly used, a frequency of failures of the laser oscillation device can be also decreased.

Thus, the laser oscillation device of the present invention has been described using the fiber laser 10 or the DDL 30 as an example, to which the present invention is not limited, and can be also applied to any laser oscillation device and laser processing system within the scope of the technical idea of the present invention.

While the present invention has been described using typical embodiments, it will be understood by a person skilled in the art that modifications to the embodiments as described above and various other changes, deletions, and additions can be made without departing from the scope of the present invention.

### Effects of the Invention

According to an aspect of the present invention, every time each of the light sources is driven, a value in which a weighting coefficient determined according to a value of a current that has driven the light sources is multiplied by a drive time of the light sources is cumulated, whereby a use frequency of and a load on each light source so far can be numericalized. Further, the storage unit of the instruction unit stores the cumulative value obtained from the cumulation as described above while allowing the same to correspond to each of the light sources. Consequently, during the low output instruction, a part from of the plurality of light sources is selected and allowed to radiate, the light sources with a less use frequency and a less load so far can be grasped from the cumulative value stored in the storage unit of the instruction unit and preferentially used. As a result, concentration of a load on a specific light source in an output control during a low output instruction can be prevented. In addition, since a specific light source is not repeatedly used, a frequency of failures of the laser oscillation device can be also decreased.

According to another aspect of the present invention, through the light sources unselected during the laser output instruction, a current more than zero and less than the radiation threshold value is allowed to flow so that an effect in which an output response property when a switch from the low output instruction to the high output instruction is made is improved can be obtained.

According to still another aspect of the present invention, numerical values of the cumulative value of each light source that are stored in the storage unit of the instruction unit are uniformly reduced in a periodical manner so that the cumulative value can be stored in the storage unit without overflow of the cumulative value beyond a storage capacity of the storage unit.

According to still another aspect of the present invention, the storage unit that stores a table in which and from which the cumulative value of each light source can be written and read out is also provided to the resonators. Thereby, confirmation of a use frequency and estimation of a lifetime, and the like, of each light source with respect to each resonator can be performed. Further, when the resonators are changed, numerical values in the table in the storage unit can be written over and reset.

According to still another aspect of the present invention, the configuration in which the plurality of light sources are controlled per a group unit when the number of the light sources is large allows calculation of the cumulative value as described above and storage volume to be reduced compared to a case in which the light sources are separately controlled, which accordingly simplifies the control.

1. A laser oscillation device comprising:
a resonator including at least two light sources; and
a multiplexer that multiplexes light radiated from the at least two light sources, wherein the laser oscillation device includes:
a current control unit for variably controlling a current that drives each of the light sources;
a selection unit for selecting the light sources to radiate from among the at least two light sources; and
an instruction unit for giving instructions to the current control unit and the selection unit, respectively,
the instruction unit includes a storage unit for cumulating a value in which a weighting coefficient determined according to a value of a current that has driven the light sources is multiplied by a drive time of the light sources every time each of the light sources is driven, and storing a cumulative value obtained from thus cumulating while allowing the same to correspond to each of the light sources,
wherein the laser oscillation device (10, 30) is configured such that according to an output range of a laser output instruction to the laser oscillation device, a number of the light sources to radiate is determined, and by the number determined, the light sources are configured to be selected in an order from the smaller cumulative value by the selection unit, and only the selected light sources are allowed to radiate by the current control unit.

2. The laser oscillation device according to claim 1, wherein the light sources are semiconductor lasers.

3. The laser oscillation device according to claim 1, wherein the light sources are semiconductor lasers for excitation, and the resonator includes an excitation medium that is excited by light of the semiconductor lasers for excitation.

4. The laser oscillation device according to claim 1, wherein the instruction unit is configured to control a rest of the light sources except the selected light sources by a current more than zero and less than a radiation threshold value by the current control unit and the selection unit.

5. The laser oscillation device according to claim 1, wherein the instruction unit is configured to uniformly subtract a numerical value corresponding to the minimum cumulative value from among the cumulative value of each of the light sources that is stored in a storage unit of the instruction unit from the cumulative value of each of the light sources at a predetermined timing.

6. The laser oscillation device according to claim 1, wherein the resonator includes an additional storage unit, and the additional storage unit stores a table in which and from which the cumulative value of each of the light sources can be written and read out.

7. The laser oscillation device according to claim 1, wherein the resonator includes a plurality of groups composed of the plurality of light sources, and wherein the laser oscillation device is configured such that the plurality of light sources are allowed to radiate per each of the groups.
